(19) United States
(12) Patent Application Publication
(10) Pub. No.: US 2004/0108136 A1
(43) Pub. Date: Jun. 10, 2004

(54) Structure comprising a barrier layer of a tungsten alloy comprising cobalt and/or nickel

(75) Inventors: Panayotis Andricacos, Croton-on-Hudson, NY (US); Steven H. Boettcher, Fishkill, NY (US); Sandra G. Malhotra, Beacon, NY (US); Milan Paunovic, Port Washington, NY (US); Craig Ransom, Hopewell Junction, NY (US)

Correspondence Address: CONNOLLY BOVE LODGE & HUTZ LLP, SUITE 800, 1990 M STREET NW, WASHINGTON, DC, 20036-3425, US

(73) Assignee: International Business Machines Corporation, Armonk, NY (US)

(21) Appl. No.: 10/309,123

(22) Filed: Dec. 4, 2002

(51) Int. Cl. H05K 1/11

(52) U.S. Cl. 174/262

(57) ABSTRACT

An interconnection structure comprising a substrate having a dielectric layer with a via opening therein; wherein the opening has an underlayer of cobalt and/or nickel therein, barrier layer of an alloy of cobalt and/or nickel; and tungsten is provided.

### FIELD OF THE INVENTION

The present invention relates to interconnection wiring on electronic devices such as on integrated circuit (IC) chips and more particularly to encapsulated copper interconnection in integrated circuits.

### BACKGROUND OF THE INVENTION

In the past, Al—Cu and its related alloys were the preferred alloys for forming interconnections on electronic devices such as integrated circuit chips. The amount of Cu in Al—Cu is typically in the range of 0.3 to 4 percent.

Replacement of Al—Cu by Cu and Cu alloys as a chip interconnection material results in advantages of performance. Performance is improved because the resistivity of Cu and certain copper alloys is less than the resistivity of Al—Cu; thus narrower lines can be used and higher wiring densities will be realized.

The advantages of Cu metallization have been recognized by the semiconductor industry. In fact, the semiconductor industry is rapidly moving away from aluminum and is adopting copper as the material of choice for chip interconnects because of its high conductivity and improved reliability.

Manufacturing of chip interconnects involves many process steps that are interrelated. In particular, copper interconnects are manufactured using a process called “Dual Damascene” in which a via and a line are fabricated together in a single step. A few of the important integration issues that need to be overcome to successfully fabricate Dual Damascene copper interconnects is the continuity of the barrier and seed layer films and the ability of the copper electroplating process to yield seamless and void-free deposits along the Dual Damascene sidewalls, bottom wall and along the center of the wiring. In addition, the International Technology Roadmap for Semiconductors, 1999 Edition, calls for small via diameters and higher aspect ratios in future interconnect metallizations.

In many prior art techniques, copper is electrodeposited on a copper seed layer which in turn is deposited onto a diffusion layer. Both diffusion barrier and Cu seed layer are typically deposited using physical vapor deposition (PVD), ionized physical vapor deposition (IPVD), or chemical vapor deposition (CVD) techniques (Hu et al., Mat. Chem. Phys., 52 1998)5). All of these methods, PVD, IPVD, and CVD require special tooling along with a vacuum. Moreover, the diffusion barrier is frequently composed of two layers (e.g. Ti/TiN bilayer barrier).

Accordingly, room exists for improvement in the prior art for simplifying the processing and/or the required layers.

### SUMMARY OF THE INVENTION

The present invention makes it possible to completely encapsulated copper interconnections for integrated circuits employing certain tungsten diffusion barrier layers. The present invention is concerned with employing a diffusion barrier layer of an electrodeposited tungsten alloy comprising cobalt and/or nickel.

The present invention makes it possible to directly deposit copper on the barrier layer by electrochemical means.

In particular, the present invention relates to an electronic structure comprising a substrate having a dielectric layer having a via opening therein; the via opening having an underlayer of cobalt, nickel or both deposited on sidewalls and bottom surfaces of the via opening; and a barrier layer on the underlayer on the sidewalls and bottom surfaces of the underlayer; wherein the barrier layer comprises an electrodeposited layer of an alloy of tungsten comprising at least one member selected from the group consisting of cobalt, nickel and mixtures thereof.

Another aspect of the present invention relates to a method for fabricating an electronic structure which comprises forming an insulating material on a substrate; lithographically defining and forming recesses for lines and/or via in the insulating material in which interconnection conductor material will be deposited; blanket depositing an underlayer of cobalt, nickel or both; electrodepositing on the underlayer a barrier layer of an alloy of tungsten comprising at least one member selected from the group consisting of cobalt, nickel and mixtures thereof.

Still other objects and advantages of the present invention will become readily apparent by those skilled in the art from the following detailed description, wherein it is shown and described preferred embodiments of the invention, simply by way of illustration of the best mode contemplated of carrying out the invention. As will be realized the invention is capable of other and different embodiments, and its several details are capable of modifications in various obvious respects, without departing from the invention. Accordingly, the description is to be regarded as illustrative in nature and not as restrictive.

### BRIEF DESCRIPTION OF THE FIGURES

FIGS. 1-6 are schematic diagram structures according to the present invention at different stages of fabrication.

### BEST AND VARIOUS MODES FOR CARRYING OUT INVENTION

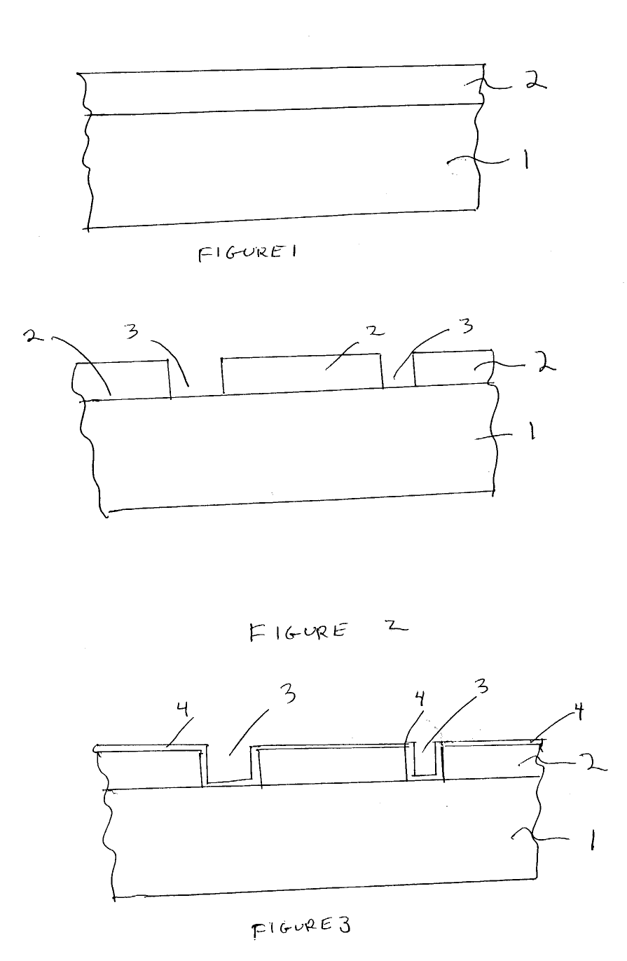

Reference will be made to the figures to facilitate an understanding of the present invention. As shown in FIG. 1, the structures according to the present invention can be obtained by providing an insulating material 2 such as silicon dioxide on a substrate 1 (e.g. a semiconductor wafer substrate).

Lines and/or vias openings 3 are lithographically defined and formed in the insulating material 2 by well-known techniques as illustrated in FIG. 2. According to the present invention an underlayer 4 of cobalt and/or nickel and preferably cobalt is blanket deposited onto the structure as illustrated in FIG. 3. The deposition is typically carried out by CVD (chemical vapor deposition) or preferably by sputtering. The sputtering is typically achieved by PVD (physical vapor deposition) or IPVD (ionized physical vapor deposition). The sputtering is typically carried out employing source powers of about 1-5 kilowatt, and inert gas pressures (e.g. argon) of about 10-80 mTorr. Further discussion of the deposition of the underlayer is not deemed necessary since such would be readily ascertainable by persons skilled in the art and aware of this disclosure.

The cobalt and/or nickel underlayer is typically about 10 to about 200 nanometers and more typically about 50 to about 100 nanometers.

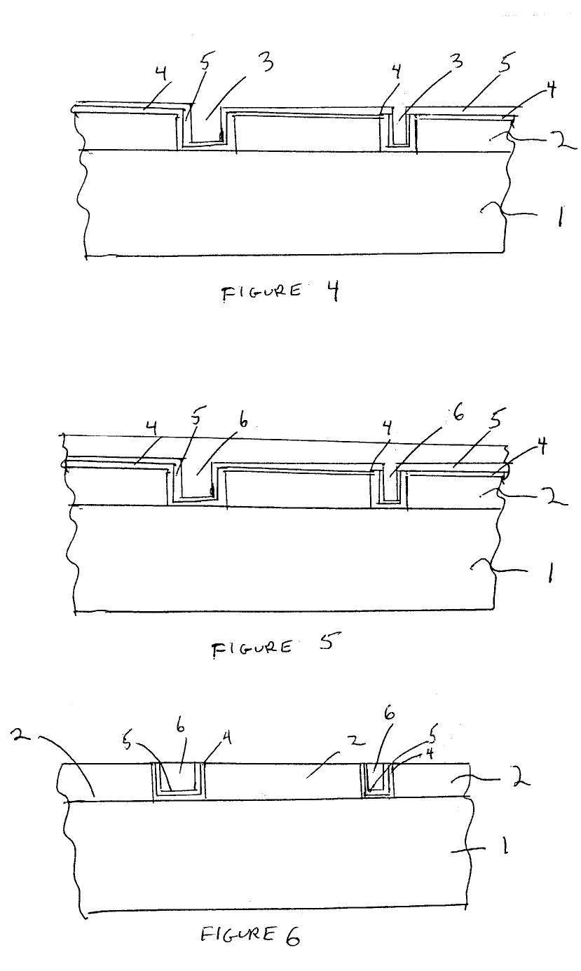

A barrier layer 5 is next deposited on the underlayer 4 as illustrated in FIG. 4. The barrier layer 5 is an alloy of cobalt and/or nickel. The tungsten-selected alloy preferably contains the same as the underlayer 4 metal. For instance, when the underlayer 4 is cobalt, the barrier layer 5 is an alloy of cobalt and tungsten. The alloy can also include minor alloying amounts of other materials such as phosphorus.

The alloy typically contains at least about 2 atomic percent of tungsten, and more typically about 15 to about 20 atomic percent of tungsten.

The ability to include over 10 atomic percent of tungsten is quite surprising. For example, in the prior art the content of W in Co—W(P) alloy, deposited electrolessly, is up to only 7 percent. (Lopatin et al., Mat. Res. Soc. Symp. Proc. Vol. 451 (1997)463). Employing the present invention makes it possible to produce Co—W(P) alloys with the content of W up to about 20 atomic %, and Co—W alloys with W content up to about 15 atomic percent.

The barrier layer 5 is typically about 5 to about 200 nanometers thick and more typically about 10 to about 100 nanometers thick.

The barrier layer 5 is typically electrodeposited onto the sputtered underlayer 4. The solution for electrodepositing the barrier layer 5 comprises a source of tungsten ions such as (NH₄)₂WO₄ and (NH₄)₁₀W₁₂O₄₁; a source of cobalt ions such as CoCl₂ or CoSO₄ or a source of nickel ions such as NiCl₂, Ni(NO₃)₂ or NiSO₄; complexing agents, surfactants and pH adjusters. For instance, a suitable solution for electrodeposition of Co—W alloy contains: (NH₄)₂WO₄(or (NH₄)₁₀W₁₂O₄₁), CoCl₂(or CoSO₄), Na₃-citrate, NH₄Cl, Triton X-114, and NH₄OH to pH 9.26. A solution for electrodeposition of Co—W(P) contains (NH₄)₂WO₄, CoCl₂, Na₃-citrate, boric acid, Triton X-114, NaOH to pH 8.90, and Na₂H₂PO₂. The extent of complexation of Co²⁺ ions and the pH of the solution are adjusted in such a way that a desired structure of the alloy and a desired adhesion are obtained, which can be readily adjusted by persons skilled in the art once aware of this disclosure. In electrodeposition of alloys the value of the ratio of the amount of deposited metal (M₁/M₂, or, the value of the current-density ratio (i₁/i₂) depends upon the exchange-current density, the transfer coefficients, the equilibrium potential, and upon the potential difference across the interface. The equilibrium potential, and in some cases the exchange-current density and the transfer coefficient, can be changed by complexing metal ions in solution and changing pH. The equilibrium potential depends on concentration depends on concentration (activity) of metal ions and ligand, complexing agent of that ion, according to the Nernst equation. Thus, in electrodeposition of alloys, the composition of an alloy can be changed by changing the concentration of metal ions in the solution and pH. Persons skilled in the art can use this method and the change of the potential difference across the interface (overpotential) to produce desired structure and properties of alloy.

The content of W can be controlled by varying the deposition current density. The current density is typically about 5-20 mA/cm². The diffusion barriers prevent diffusion of Cu from the interconnection into the insulator (e.g. SiO₂ or other insulator with lower dielectric constant, ε) and Si substrate.

A copper or copper alloy layer 6 is then deposited onto the diffusion barrier layer 5 as illustrated in FIG. 5. The copper can be deposited directly on the barrier layer 5 without any additional seed layer by electrochemical deposition such as electroplating or electroless plating. Examples of suitable electroplating compositions are disclosed in U.S. Ser. No. 09/348,632 disclosure of which is incorporated herein by reference. The copper plating is employed to fill the lines and/or vias openings 3.

Any layers 4, 5 and 6 present on the top surface of the substrate can be removed as illustrated in FIG. 6 by, for example, chemical mechanical polishing to provide a planarized structure with copper being flush with the substrate and to achieve electrical isolation of individual lines and/or vias.

If desired, the chemical mechanical polishing can be carried out prior to depositing the copper in the event of electrtoless deposition.

The technique of the present invention can be used for single and dual daamascene structures.

The following non-limiting examples are presented to further illustrate the present invention.

### EXAMPLE 1

Co—W liner is electrodeposited, onto a patterned wafer with 100 nm of blanket sputtered Co, from an alkaline solution of the following composition:

| | | |
|---|---|---|
| (NH₄)₁₀W₁₂O₄₁.H₂O | 5-30 | g/L |
| CoCI₂.6H₂O | 10-40 | g/L |
| Na₃-citrate.2H₂O | 20-80 | g/L |
| NH₄Cl | 15/40 | g/L |
| pH 9.26, adjusted with NH₄OH | | |
| Triton X-114 | 0.05-1.0 | mL/L |
| Temperature | 20-35° | C. |

Co Anode

Electrodeposition is done at a rate of 10 mA/cm².

Auger analyses of the composition of the deposit shows that the deposited alloy has 15.1% W. Deposit in the line (interconnect) 0.35 μm wide is conformal and about 200 nm thick.

### EXAMPLE 2

Example 1 is repeated except that he rate of deposition is 20 mA/cm². Auger analyses of the deposit shows that the deposited alloy has 7.6% of W. Deposit in the line 0.35 μm wide is conformal and about 160 nm thick.

### EXAMPLE 3

Co—W(P) liner is electrodeposited, onto a patterned wafer with 100 nm of blanket sputtered Co, from an alkaline solution of the following composition:

| | | |
|---|---|---|
| (NH₄)₂WO₄ | 5-25 | g/L |
| CoCI₂.6H₂O | 10-40 | g/L |
| Na₃-citrate.2H₂O | 20-80 | g/L |
| NH₄Cl | 15-40 | g/L |
| Na₂H₂PO₂ | 5-20 | g/L |
| pH 8.11, adjusted with NH₄OH | | |
| Triton X-114 | 0.05-1.0 | mL/L |
| Temperature | 60-85° | C. |

Co Anode

Electrodeposition is done at a rate of 5 mA/cm².

Auger analyses of the deposit shows that the deposited alloy has 12.3% W and 2.9% P. Deposit is about 75 nm thick.

### EXAMPLE 4

Experiment 3 is repeated except that the rate of deposition is 10 mA/cm².

Auger analyses of the deposit shows that the deposited alloy has 18.8% W and 2.4% P. Deposit is about 70 nm thick.

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. An electronic structure comprising
a substrate having a dielectric layer having a via opening therein; the via opening have an underlayer of cobalt, nickel or both deposited on sidewalls and bottom surfaces of the via opening; and
a barrier layer on the underlayer on the sidewalls and bottom surfaces of the underlayer; wherein the barrier layer comprises an electrodeposited layer of an alloy comprising at least one member selected from the group consisting of cobalt, nickel and mixtures thereof; and tungsten.

2. The structure of claim 1 which further comprises copper or a copper alloy on the barrier layer and filling the via opening.

3. The structure of claim 1 wherein the dielectric layer comprises silicon dioxide.

4. The structure of claim 1 wherein the via opening is about 100 to about 500 nanometers thick.

5. The structure of claim 1 wherein the underlayer is about 10 to about 200 nanometers thick.

6. The structure of claim 1 wherein the underlayer comprises cobalt.

7. The structure of claim 1 wherein the barrier layer comprises cobalt-tungsten alloy.

8. The structure of claim 1 wherein the alloy comprises at least about 2 atomic percent of tungsten.

9. The structure of claim 1 wherein the alloy comprises about 15 atomic percent of tungsten.

10. The structure of claim 1 wherein the alloy comprises about 19 atomic percent of tungsten and is an alloy of cobalt-tungsten and phosphorous.

11. The structure of claim 10 wherein alloy comprises about 2 to about 10 percent phosphorous.

12. The structure of claim 1 wherein the barrier layer is about 5 to about 200 nanometers thick.

13. A method for fabricating an electronic structure which comprises forming an insulating material on a substrate; lithographically defining and forming recesses for lines and/or via in the insulating material in which interconnection conductor material will be deposited;
blanket depositing an underlayer of cobalt, nickel or both;
electrodepositing on the underlayer a barrier layer of an alloy comprising at least one member selected from the group consisting of cobalt, nickel and mixtures thereof; and tungsten.

14. The method of claim 1 which further comprises depositing copper or a copper alloy on the barrier layer to fill the recesses.

15. The method of claim 14 wherein the copper or copper alloy is deposited by electro-chemical deposition directly onto the barrier layer.

16. The method of claim 14 which further comprises planarizing the structure.

17. The method of claim 13 wherein the blanket depositing is sputtering or CVD.

18. The method of claim 13 wherein the underlayer comprises cobalt.

19. The method of claim 13 wherein the barrier layer comprises cobalt-tungsten alloy.

20. The method of claim 13 wherein the alloy comprises at least about 2 atomic percent of tungsten.

21. The method of claim 13 wherein the alloy comprises about 15 atomic percent of tungsten.

22. The method of claim 13 wherein the alloy comprises about 19 atomic percent of tungsten and is an alloy of cobalt-tungsten and phosphorous.

23. The method of claim 22 wherein alloy comprises about 2 to about 10 percent phosphorous.

24. The method of claim 13 wherein the barrier layer is about 5 to about 200 nanometers thick.

25. The method of claim 13 wherein the dielectric layer comprises silicon dioxide.

26. The method of claim 13 wherein the via opening is about 100 to about 500 nanometers thick.

27. The method of claim 13 wherein the underlayer is about 10 to about 200 nanometers thick.

28. The method of claim 13 wherein the blanket depositing is PVD or IPVD.

29. The structure obtained by the method of claim 13.
